(19) United States
(12) Patent Application Publication
(10) Pub. No.: US 2007/0032022 A1
(43) Pub. Date: Feb. 8, 2007

(54) Mask read only memory (ROM) and method of fabricating the same

(75) Inventors: Hong-Kook Min, Yongin-si (KR); Chang-Mo Park, Seongman-si (KR); Sung-Kyoo Park, Seoul (KR)

Correspondence Address: F. CHAU & ASSOCIATES, LLC, 130 WOODBURY ROAD, WOODBURY, NY, 11797, US

(73) Assignee: Samsung Electronics Co., LTD, Suwon-si (KR)

(21) Appl. No.: 11/499,375

(22) Filed: Aug. 4, 2006

(30) Foreign Application Priority Data
Aug. 8, 2005 (KR) 2005-72354

(51) Int. Cl. H01L 21/8234

(52) U.S. Cl. 438/275

(57) ABSTRACT

The Mask ROM includes a plurality of doped lines arranged on a substrate of a first conductivity. The doped lines have a second conductivity. In addition, the Mask ROM further includes an insulation film covering the substrate, a plurality of interconnections intersecting the doped lines in parallel and arranged on the insulation film, an isolative doped region of the first conductivity arranged at the doped line of at least one intersecting place selected from intersecting places between the interconnections and the doped lines, a first contact plug penetrating the insulation film at the selected intersecting place and connecting the isolative doped region to the interconnection, and a second contact plug penetrating the insulation film at a deselected intersecting place and connecting the doped line to the interconnection.

### CROSS-REFERENCE TO RELATED APPLICATIONS

This U.S. non-provisional patent application claims priority under 35 U.S.C. § 119 of Korean Patent Application 2005-72354 filed on Aug. 8, 2005, the disclosure of which is hereby incorporated by reference herein in its entirety.

### BACKGROUND

1. Technical Field

The present disclosure relates to semiconductor memory devices and to methods of fabricating the same, an in particular relates to a mask read-only memory (mask ROM) and to methods of fabricating the same.

2. Description of the Related Art

Mask ROMs as semiconductor memory devices have the property of non-volatility and thus these memory devices retain their data even when their power supplies are interrupted. Also, with mask ROMs, typically data may only be read but not written. The mask ROM has unit cells formed of metal-oxide-transistor (MOS) transistors. In the mask ROM, the state of data is differentiated into logic ‘1’ and logic ‘0’ by employing MOS transistors which are turned off and on respectively in response to a constant gate voltage. A typical mask ROM is configured as follows.

FIG. 1 is a sectional view of a conventional mask ROM.

Referring to FIG. 1, the mask ROM cell includes a depletion transistor a and an enhancement transistor b. The transistors a and b are all NMOS transistors. Each transistor a or b is composed of a gate electrode 3 arranged over a P-type semiconductor substrate 1, a gate oxide film 2 interposed between the gate electrode 3 and the semiconductor substrate 1, and N-type source and drain regions 4a and 4b located on both sides of the gate electrode 3.

The depletion transistor a has a first channel region 5a with depletion space or is doped with N-type impurities. Thus, even when 0V is applied to the gate electrode 3, the depletion transistor a is turned on. To the contrary, the enhancement transistor b has a second channel region 5b doped with P-type impurities. Thus, the enhancement transistor b is turned off when 0V is applied to the gate electrode 3. Using such transistors a and b being turned on and off, a binary logic state of data is distinguished into ‘1’ or ‘0’ and read out therefrom.

However, there may be several difficulties associated with the above-mentioned conventional mask ROM. First, it may be difficult to integrate it into high density. For instance, as the mask ROM cell is composed of transistors, there may be a short channel effect or drain induced barrier lowering (DIBL) phenomenon. Therefore, as a result, it may be difficult to shrink the dimensions of the mask ROM cell. Further, as the mask ROM cell should have a plane area for the source and drain regions 4a and 4b, the shrinking-down of the mask ROM may be made even more difficult.

In addition, it may be also be difficult for the conventional mask ROM to be treated with a coding process that writes data therein. Usually, the first channel region 5a of the depletion transistor a is formed by selectively implanting N-type ionic impurities therein. In this regard, a technique of conducting the selective ion implantation before forming the gate electrode 3 has been proposed. However, in this case, after obtaining data information required by a customer, processing steps for coding the data information, forming the gate electrode 3, forming the source and drain regions 4a and 4b, and forming subsequent interconnections may each be required. Consequently, the above proposed technique may significantly lengthen the turn-around time (TAT) required for completing the mask ROM after obtaining the customers' data information.

Thus, for shortening the TAT for completing the mask ROM, a technique of conducting the selective ion implantation after forming the gate electrode 3 has been proposed. In this case, ionic impurities for the selection ion implantation penetrate the gate electrode 3 and the gate oxide film 2 and then are injected into the first channel region 5a. As the ionic impurities penetrate the thick gate electrode 3, these ionic impurities may be irregularly implanted into the first channel region 5a. Moreover, the ionic impurities may damage the gate electrode 3 and the gate oxide film 2. As a result, the characteristics of the mask ROM cells may therefore be deteriorated, thereby possibly causing operating malfunctions in the device.

Thus, there is a need for an improved mask ROM and method of fabricating the same which prevents the above-mentioned difficulties of the conventional mask ROMs from occurring.

### SUMMARY OF THE INVENTION

In accordance with an exemplary embodiment of the present invention a mask Read Only Memory (ROM) is provided. The Mask ROM includes a plurality of doped lines arranged at a substrate of a first conductivity. The doped lines have a second conductivity. In addition, the Mask ROM further includes an insulation film covering the substrate, a plurality of interconnections intersecting the doped lines in parallel and arranged on the insulation film, an isolative doped region of the first conductivity arranged at the doped line of at least one intersecting place selected from intersecting places between the interconnections and the doped lines, a first contact plug penetrating the insulation film at the selected intersecting place and connecting the isolative doped region to the interconnection, and a second contact plug penetrating the insulation film at a deselected intersecting place and connecting the doped line to the interconnection.

According to an exemplary embodiment, the first conductivity may be N-type and the second conductivity may be P-type. In this case, during a read operation, the mask ROM is adapted to receive a first voltage applied to a selected one of the interconnections which is higher than a second voltage applied to a selected one of the doped lines. The first voltage may be a precharging voltage while the second voltage may be a ground voltage.

According to an exemplary embodiment, the first conductivity is P-type and the second conductivity is N-type. In this case, during a read operation, the mask ROM is adapted to receive a first voltage applied to a selected one of the interconnections which is lower than a second voltage applied to a selected one of the doped lines.

According to an exemplary embodiment, the doped lines may be word lines and the interconnections may be bit lines. The mask ROM may further include a plurality of field isolation films defining linear active regions arranged in parallel with each other in the substrate. The active regions are isolated from each other and the doped line is disposed in the active region. The doped line may be lower than the isolative doped region in impurity concentration. Also, the interconnection may include a conductive material lower than doped silicon in resistivity.

In accordance with another exemplary embodiment of the present invention, a method of fabricating a mask Read Only Memory (ROM) is provided. The method includes forming a plurality of doped lines in parallel at a substrate of a first conductivity. The doped lines being set in a second conductivity. Moreover, the method further includes forming an insulation film to cover the substrate, patterning the insulation film to form a plurality of contact holes exposing the doped lines, implanting ionic impurities into the doped line through a selected contact hole to form an isolative doped region, forming contact plugs to fill the contact holes and forming a plurality of interconnections that intersect the doped lines in parallel on the insulation film and link with the contact plugs.

In an exemplary embodiment, the first conductivity may be N-type while the second conductivity may be P-type. In this case, during a read operation, a first voltage applied to a selected one of the interconnections is preferred to be higher than a second voltage applied to a selected one of the doped lines.

Alternatively, the first conductivity may be P-type while the second conductivity may be N-type. In this case, during a read operation, a first voltage applied to a selected one of the interconnections may be lower than a second voltage applied to a selected one of the doped lines.

The doped line may be a word line while the interconnection may be a bit line. The method may further comprise forming a plurality of field isolation films to define linear active regions arranged in parallel with each other in the substrate. Thereby, the doped lines are disposed in the active regions, respectively.

The forming of the isolative doped regions may comprise forming a mask pattern to selectively expose and cover the contact holes on the substrate, implanting ionic impurities of the first conductivity into the substrate through the exposed contact holes under the mask pattern, removing the mask pattern and activating the ionic impurities implanted into the substrate.

The doped line may be lower than the isolative doped region in impurity concentration. The interconnection may include a conductive material lower than doped silicon in resistivity.

### BRIEF DESCRIPTION OF THE FIGURES

Exemplary embodiments of the present invention can be understood in more detail from the following description taken in conjunction with the accompanying drawings, in which:

FIG. 1 is a sectional view of a conventional mask ROM;

FIG. 2 is a plan view illustrating a mask ROM in accordance with an exemplary embodiment of the invention;

FIG. 3A is a sectional view taken along with I-I′ of FIG. 2;

FIG. 3B is a sectional view taken along with II-II′ of FIG. 2;

FIG. 4A through 8A are sectional views illustrating the procedure of fabricating the mask ROM in accordance with an exemplary embodiment of the invention, taken along with I-I′ of FIG. 2; and

FIGS. 4B through 8B are sectional views illustrating the procedure of fabricating the mask ROM in accordance with the exemplary embodiment of the invention, taken along with II-II′ of FIG. 2.

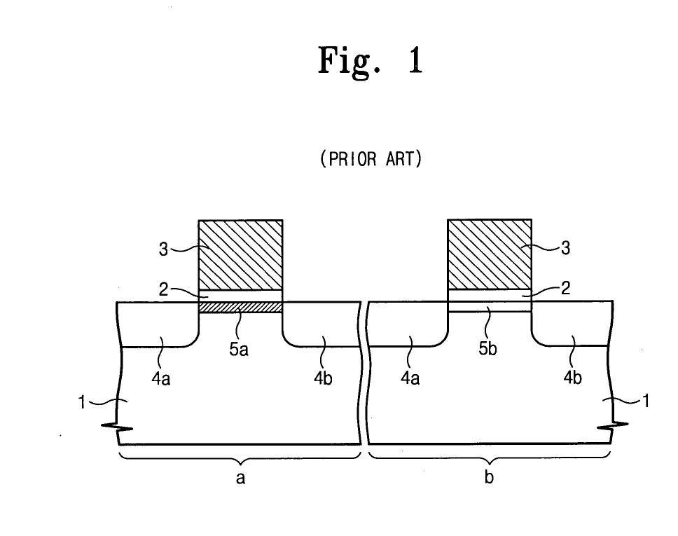

### DETAILED DESCRIPTION OF THE EXEMPLARY EMBODIMENTS

Exemplary embodiments of the present invention will be described below in more detail with reference to the accompanying drawings. The present invention may, however, be embodied in different forms and should not be constructed as limited to the exemplary embodiments set forth herein.

Hereinafter, an exemplary embodiment of the present invention will be described in conjunction with the accompanying drawings.

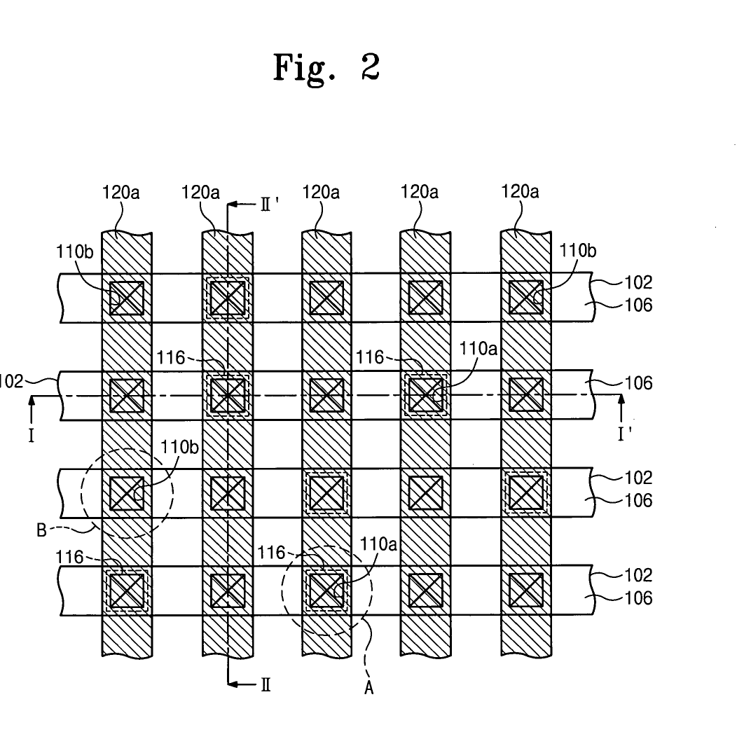

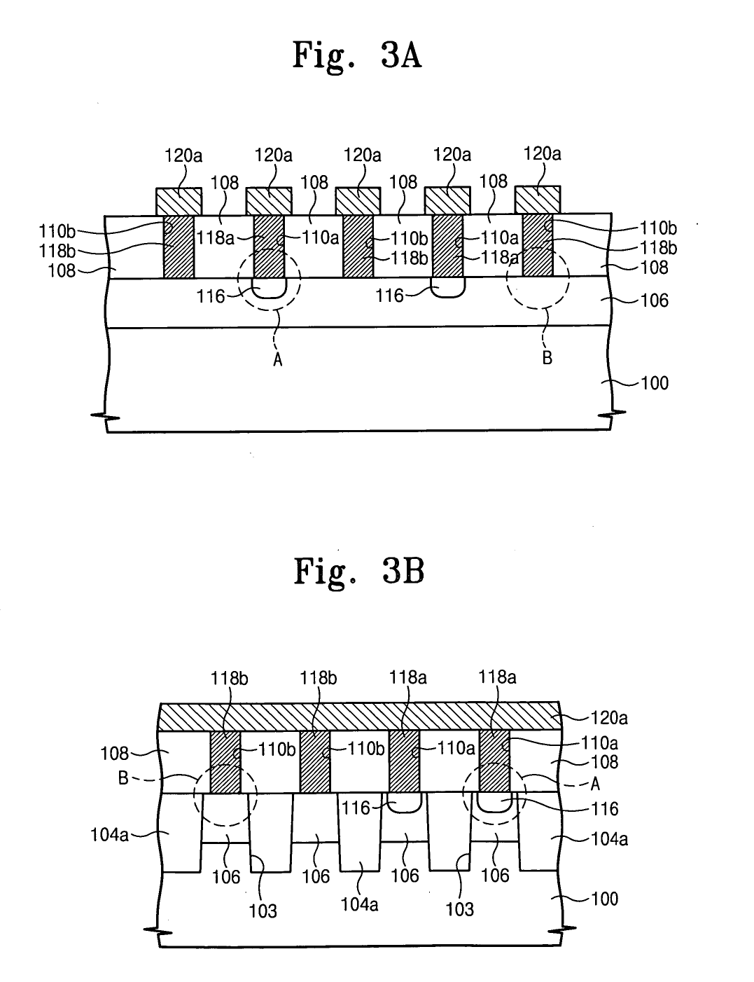

FIG. 2 is a plan view illustrating a mask ROM in accordance with an exemplary embodiment of the invention. FIG. 3A is a sectional view taken along with I-I′ of FIG. 2, and FIG. 3B is a sectional view taken along with II-II′ of FIG. 2.

Referring to FIGS. 2, 3A, and 3B, field isolation films 104a are formed to confine active regions 102 in predetermined regions of a semiconductor substrate 100 (hereinafter, referred to as ‘substrate’). The active regions 102 are linearly arranged in parallel with each other. The substrate 100 is doped with impurities of first conductivity. The substrate 100 may be doped by a well of the first conductivity.

In the active regions 102, doped lines 106 are arranged with impurities of a second conductivity. The doped lines 106 are configured in the shape of lines, extending along the linear active regions 102. In other words, the doped lines 106 are arranged in parallel and are isolated from each other on the substrate 100. Between adjacent doped lines 106 are arranged the field isolation films 104a.

An insulation film 108 is covered over the entire substrate 100. The insulation film 108 may be formed of, for example, silicon oxide. On the insulation film 108, interconnections 120a are arranged in parallel, intersecting the doped lines 106. The interconnections 120a are also isolated from each other. The interconnections 120a are preferred to be bit lines. It is also preferred for the interconnections 120a to be connected with amplifiers.

Intersecting places between the interconnections 120a and the doped lines 106 are correspondent to cell regions. Namely, pluralities of the cell regions are arranged in a second dimension along the directions of rows and columns on the substrate 100. In FIG. 2, the row direction is defined in parallel with the doped lines 106, while the column direction is defined in parallel with the interconnections 120a.

The cell regions are divided into first and second cell regions A and B. One of the first and second cell regions A and B stores a data bit of logic ‘1’, while the other store a-data bit of logic ‘0’. An isolative doped region 116 is disposed in the doped line 106 at the first cell region A. The isolative doped region 116 is doped with impurities of the first conductivity. The second cell region B does not include the isolative doped region 116.

First contact plugs 118a penetrate the insulation film 108 within the first cell regions A, respectively. The first contact plug 118a conductively connects the isolative doped region 116 with the interconnection 120a within the first cell region A. The first contact plug 118a fills up a first contact hole 110a penetrating the insulation film 108 and exposes the isolative doped region 116. Second contact plugs 118b penetrate the insulation film 108 within the second cell regions B, respectively. The second contact plug 118b conductively connects the doped line 106 with the interconnection 120a in the second cell region B. The second contact plug 118b fills up a second contact hole 110b penetrating the insulation film 108 and partially exposing the dope line 106.

One of the first and second conductivities is N-type, while the other is P-type. Accordingly, the isolative doped regions 116 of the first cell regions A form PN junctions with the doped lines 106. In other words, PN diodes are formed at the first cell regions A. Otherwise, at the second cell regions B, the second contact plugs 118b directly contact with the doped lines 106. In other words, the second cell regions B do not include PN diodes.

In a read operation of the mask ROM with this structure, it selects one of the plural cell regions A and B. A reverse bias of the PN diode applies to the selected cell region through a selected interconnection 120a and a selected doped line 106 connected to the selected cell region. Thus, when the selected cell region is the first cell region A, the selected interconnection 120a and doped line 106 are electrically disconnected from each other. Otherwise, when the selected cell region is the second cell region B, the selected interconnection 120a becomes electrically conductive with the selected doped line 106. As a result, the above-mentioned electrical disconnection and conduction are used to read a data bit from the selected cell region. Meanwhile, during the read operation, deselected interconnections 120a and doped lines 106 may be floated.

A situation in which the first conductivity is N-type while the second conductivity is P-type will now be discussed. The substrate 100 is doped with N-type impurities. The doped lines 106 are doped with P-type impurities and the isolative doped regions 116 are doped with N-type impurities. In a read operation, a first voltage applied to the selected interconnection 120a is higher than a second voltage applied to the selected doped line 106. Accordingly, between the selected interconnection and doped line, 120a and 106, a voltage is supplied which is correspondent with a reverse bias between the isolative doped region 116 and the doped line 106. As a result, when the selected one is the first cell region A, the selected interconnection and doped line, 120a and 106, are electrically disconnected from each other. When the selected one is the second cell region B, the selected interconnection and doped line, 120a and 106, are conductive with each other. In this case, the first voltage applied to the selected interconnection 120a is preferred to be a precharging voltage while the second voltage applied to the selected doped line 106 is preferred to be a ground voltage. Also, the interconnections 120a may be connected to a precharging circuit.

Alternatively, now a situation will be described in which the first conductivity is P-type while the second conductivity is N-type. In this situation, the substrate 100 is doped with P-type impurities. The doped lines 106 are doped with N-type impurities and the isolative doped regions 116 are doped with P-type impurities. In a read operation, the first voltage applied to the selected interconnection 120a is lower than the second voltage applied to the selected doped line 106. Accordingly, a voltage that is correspondent with a reverse bias between the isolative doped region 116 and the doped line 106 is supplied between the selected interconnection and doped line, 120a and 106. As a result, when the selected one is the first cell region A, the selected interconnection and doped line, 120a and 106, are electrically disconnected from each other by the selected cell region. When the selected one is the second cell region B, the selected interconnection and doped line, 120a and 106, are conductive with each other through the selected cell region. In this case, the first voltage applied to the selected interconnection 120a is preferred to be the ground voltage while the second voltage applied to the selected doped line 106 is preferred to be the precharging voltage. Moreover, the doped lines 106 may be connected to the precharging circuit.

The impurity concentration of the doped lines 106 is preferred to be lower than that of the isolative doped regions 115 to reduce parasitic electrostatic capacitance caused by deselected cell regions sharing the selected interconnection 120a, thereby providing a mask ROM operable in a high frequency.

During the read operation, there may be parasitic capacitance caused by depletion regions generated in the doped line 106 of the deselected cell regions connected with the selected interconnection 120a. The depletion region may be present when either the first cell region A or the second cell region B is correspondent with the deselected cell region connected to the selected interconnection 120a. The parasitic capacitance can delay propagation of electrical signal transferred through the selected interconnection 120a. However, as aforementioned, the width of the depletion region may be extended by lowering impurity concentration of the doped line 106, thereby minimizing the parasitic electrostatic capacitance. Furthermore, as a result, the signal delay through the selected interconnection 120a caused by parasitic electrostatic capacitance is significantly reduced, thereby resulting in a high-speed mask ROM.

The contact plugs, 118 and 118b, and the interconnections 120a are conductively connected with each other with accompanying interfaces to the interconnections 120a. Alternatively, the contact plugs 118a and 118b may be formed by the interconnections 120a extending downward to fill up the contact holes 10a and 110b. Namely, the contact plugs 118a and 118b may be connected thereto without interfaces to the interconnections 120a.

The contact plugs 118a and 118b are made of a conductive material. For example, the contact plugs 118a and 118b may be formed of a material selected from at least the following of a metal (e.g., tungsten, or molybdenum), conductive metal nitride (e.g., titanium nitride, or tantalum nitride), and metal silicide (e.g., tungsten silicide, titanium silicide, nickel silicide, or cobalt silicide). In addition, the contact plugs 118a and 118b may contain, for example, polysilicon doped with impurities of the second conductivity (e.g. the impurities of the same conductivity with the doped lines 106).

The interconnections 120a are also made of conductive material. It is preferred for the interconnections 120a to be formed of a conductive material lower than the doped silicon in resistivity. For example, the interconnections 120a may be formed of a material selected from at least the following of a metal (e.g., tungsten, or molybdenum), conductive metal nitride (e.g., titanium nitride, or tantalum nitride), and metal silicide (e.g., tungsten silicide, titanium silicide, nickel silicide, or cobalt silicide). In addition, the interconnections 120a may contain, for example, polysilicon doped with impurities of the second conductivity.

According to the mask ROM of the present exemplary embodiment, plane areas of the cell regions A and B are restricted within those of the intersecting places on the doped line 106. Thus, the mask ROM with the cell regions A and B may be constructed in an area significantly smaller than that used for a conventional mask ROM, thereby providing a highly integrated mask ROM.

The interconnections 120a are correspondent with bit lines for outputting data. The interconnections 120a include a conductive material lower than the doped silicon in resistivity for lowering the resistivity of the interconnections 120a, thereby providing a high-speed mask ROM capable of outputting data at a very high frequency. Moreover, with the low resistivity of the bit lines, the output data loss (e.g. the amount of output voltage variation) may be minimized. According to this exemplary embodiment, the data sensing operation is carried out even in cell regions which are apart from a sense amplifier, thereby improving the data sensing margin of the mask ROM.

In addition, the doped lines 106 may be lower than the isolative doped regions 116 in impurity concentration. Thus, as aforementioned, the parasitic electrostatic capacitance that is caused by the deselected cell regions connected to the selected interconnection 120a may be significantly reduced. Besides, the isolative doped regions 116 and the doped lines 106 are different in the conductivity of impurities. For instance, the isolative doped regions 116 are formed by implanting ionic impurities of the first conductivity into the doped lines 106 of the second conductivity. During this, as the impurity concentration of the doped lines 106 is relatively lower than the isolative doped regions 116, the impurity concentration of the doped lines 106 at the isolative doped regions 116 may be readily neutralized. As a result, the isolative doped regions 116 can be completed relatively simply.

Next, the processing steps for fabricating the mask ROM in accordance with an exemplary embodiment of the present invention will be described.

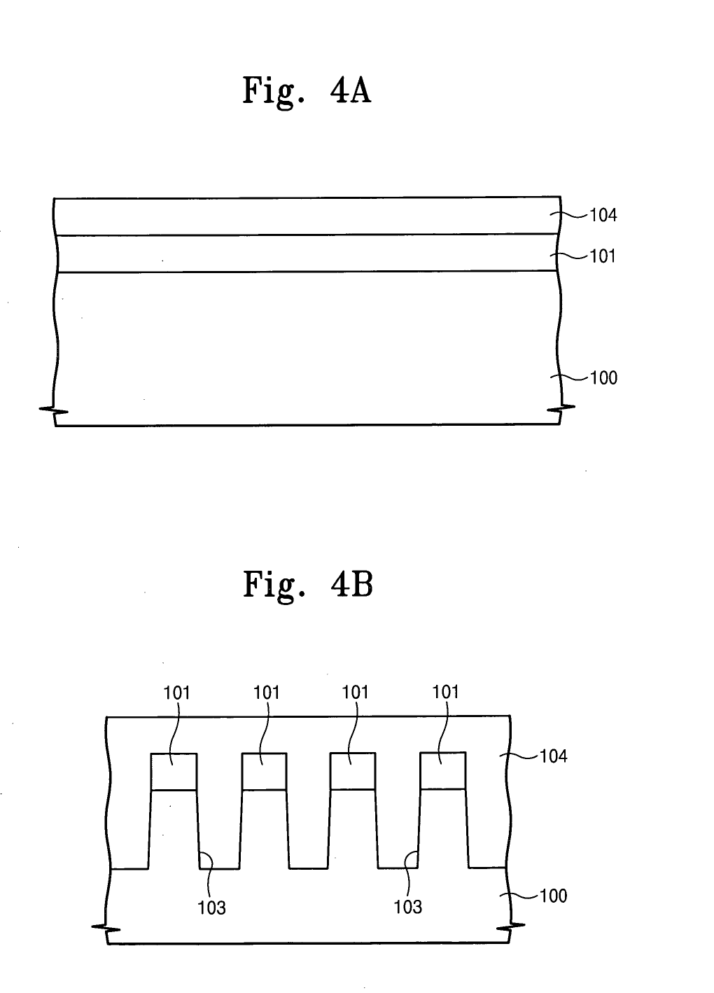

FIG. 4A through 8A are sectional views illustrating the procedure of fabricating the mask ROM in accordance with an exemplary embodiment of the invention, taken along with I-I′ of FIG. 2, and FIG. 4B through 8B are sectional views illustrating the procedure of fabricating the mask ROM in accordance with the exemplary embodiment of the invention, taken along with II-II′ of FIG. 2.

Referring to FIGS. 4A and 4B, a hard mask pattern 101 is arranged on the substrate 100. The substrate 100 is selectively etched away under the hard mask pattern 101, resulting in trenches 103 to define the active regions 102 shown in FIG. 2. The hard mask pattern 101 contains a material with etching selectivity to the substrate 100. For example, the hard mask pattern 101 may be formed of silicon nitride or silicon oxy-nitride.

After that, a field-isolating insulation film 104 is formed over the entire substrate 100 and fills the trenches 103. The field-isolating insulation film 104 may be made of, for example, silicon oxide. The field-isolating insulation film 104 may be formed of, for example, high-density plasma silicon oxide that has an improved gap-filling function.

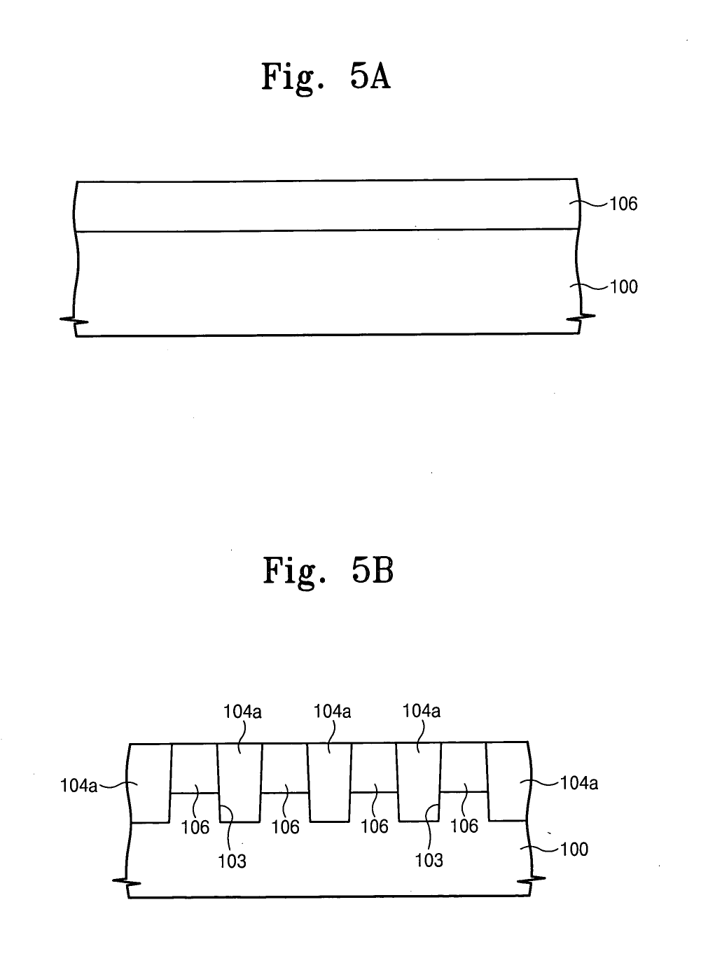

Next, referring to FIGS. 5A and 5B, the field-isolating insulation films 101 are flattened to expose the hard mask pattern 101, thereby completing the field isolation films 104a to fill up the trenches 103. The hard mask pattern 101 is then removed therefrom. From the planarization and removal of the hard mask pattern 101, the upper portions of the field isolation films 104a may be recessed in a depth close to the upward face of the substrate 100. The field isolation films 104a define the active regions 102 shown in FIG. 2. As aforementioned, the active regions 102 are formed in linear form, being arranged in parallel and isolated from each other.

The substrate 100 is doped with impurities of the first conductivity. Moreover, a well may be formed by implanting ionic impurities into the substrate 100. Namely, the substrate 100 may be doped with the first-conductivity impurities by the well forming process. The well forming process can be carried out before or after completing the field isolation films 104a. Meanwhile, the substrate 100 may be doped with the first-conductivity impurities even at the step of preparing the substrate 100.

Thereafter, ionic impurities of the second conductivity are implanted into the active regions, forming the doped lines 106. After implanting the second-conductivity impurities into the active regions, a thermal process may be carried out to activate the injected ionic impurities therein. The doped lines 106 are formed in linear form according to the configurations of the active regions. The doped lines 106 are preferred to be word lines.

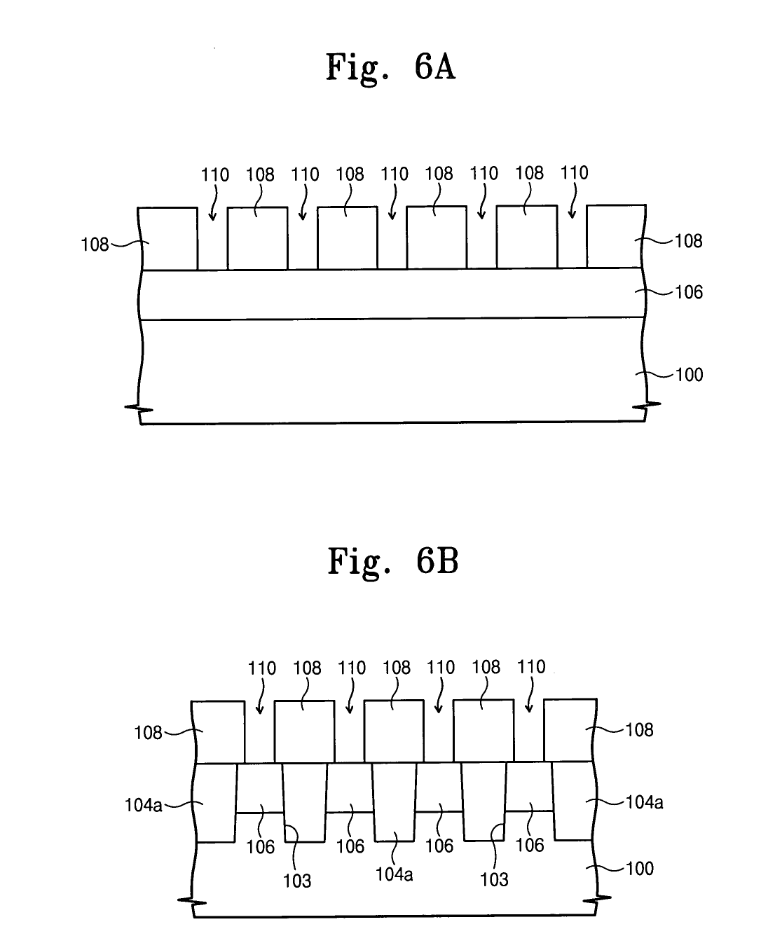

Next, referring to FIGS. 6A and 6B, the insulation film 108 is deposited over the entire substrate 100. The insulation film 108 may be made of, for example, silicon oxide. The insulation film 108 may be formed, for example, by means of a chemical vapor deposition (CVD) process.

The insulation film 108 is patterned to form the plural contact holes 110 that expose the doped lines 106. The contact holes 10 are arranged such that they are isolated from each other. The contact holes 110 are arranged in a second dimension along rows and columns.

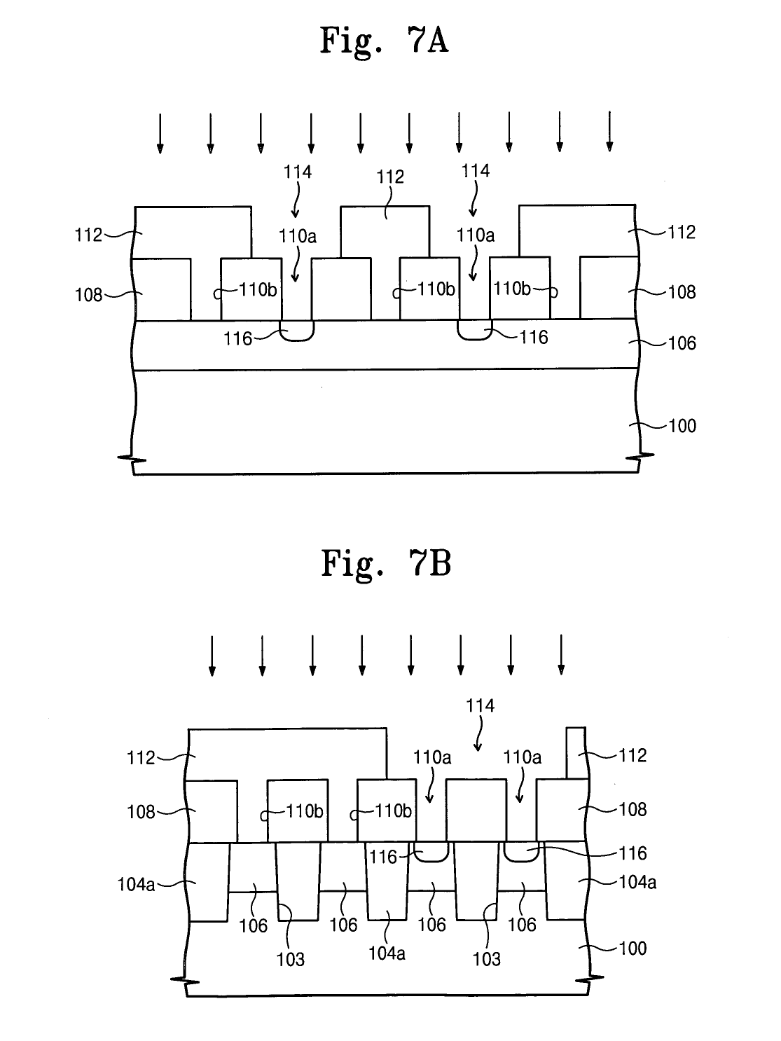

After that, referring to FIGS. 7A and 7B, a coding process is carried out with data information obtained from customers, as follows.

The contact holes 110 are differentiated into first and second contact holes 110a and 110b. The first contact holes 110a are correspondent with contact holes for selected cell regions by the data information, while the second contact holes 110b are correspondent with contact holes for deselected cell regions by the data information.

Then, a mask pattern 112 is formed over the entire substrate 100. The mask pattern 112 covers the second contact holes 110b. The mask pattern 112 may fill up the second contact holes 110b. The mask pattern 112 includes openings 114 that expose the first contact holes 110a. The mask pattern 112 exposes the first contact holes 110a, while covering the second contact holes 110b. The mask pattern 112 may be formed of, for example, a photoresist film.

Under the mask pattern 112, ionic impurities of the first conductivity are implanted into the substrate 100. According to this, the isolative doped regions 116 are formed in the doped lines 106 that are being exposed by the first contact holes 110a.

While implanting the first-conductivity ionic impurities, there are no gate electrode and gate oxide film on the doped lines 106 that are being exposed through the first contact holes 110a. In other words, on the doped lines 106, there may be just an ion-implantation buffering film, without any film or layer, for preventing damages from the ion implantation. Thus, the first-conductivity impurities may be uniformly implanted into the doped lines 106. As a result, the impurities of the first conductivity are uniformly distributed in the isolative doped regions 116.

One of the first and second conductivities is N-type, while the other is P-type. For instance, the substrate 100 and the isolative doped regions 116 may be doped with N-type impurities, while the doped lines 106 may be doped with P-type impurities. Alternatively, the substrate 100 and the isolative doped regions 116 may be doped with P-type impurities, while the doped lines 106 may be doped with N-type impurities.

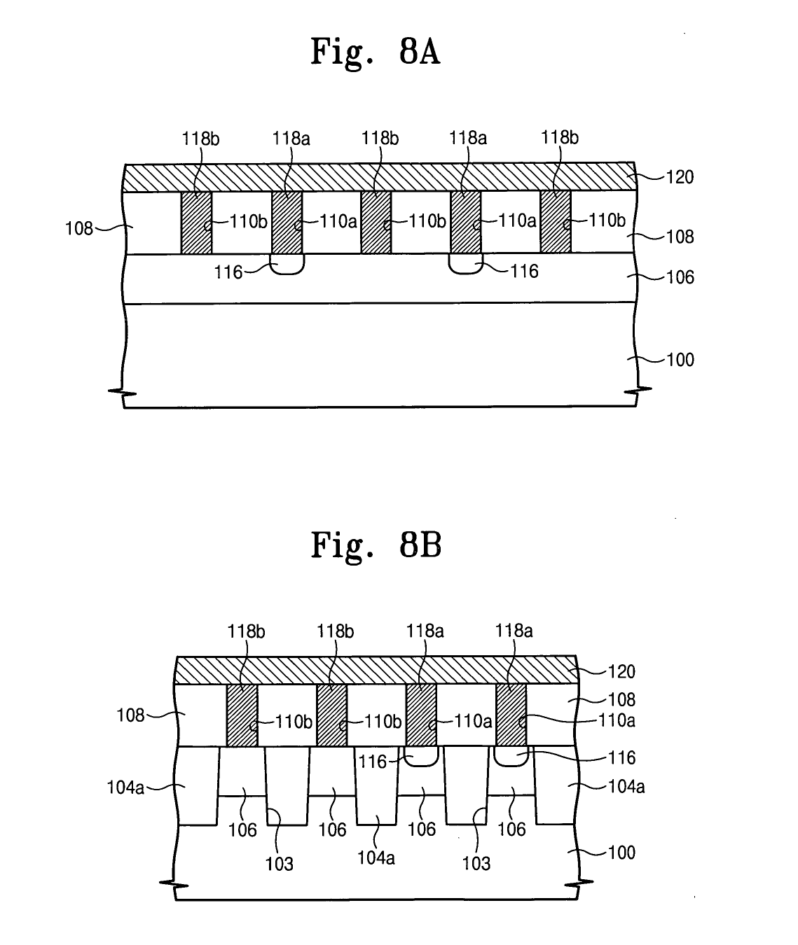

After that, referring to FIGS. 8A and 8B, the mask pattern 112 is removed from the substrate 100. Subsequent to this, it is preferred to conduct a thermal process for activating impurities in the isolative doped regions 116. The thermal process makes the impurities isotropically diffused in the isolative doped regions 116, which extends the isolative doped regions 116 wider than the first contact holes 110a.

Moreover, a cleaning process may be carried out on the doped lines 106 exposed by the contact holes 110a and 110b.

The first contact plugs 118a filling the first contact holes 110a are conductively connected with the isolative doped regions 116. In this structure, plane areas of the isolative doped regions 116 may be formed wider than the bottom faces of the first contact plugs 118a owing to the thermal process. Consequently, the isolative doped regions 116 are formed having their upward faces enough to include the bottom faces of the first contact plugs 118a to thereby prevent the first contact plugs 118a from contacting with the doped lines 106. The second contact plugs 118b filling the second contact holes 110b contact directly with the doped lines 106.

The first and second contact plugs 118a and 118b may be parts of the conductive film 120. Alternatively, the conductive film 120 may be formed after completing the first and second contact plugs 118a and 118b.

The first and second contact plugs 118a and 118b are made of a conductive material. For example, the contact plugs 118a and 118b are formed from a material selected from at least the following of a metal (e.g., tungsten, or molybdenum), conductive metal nitride (e.g., titanium nitride, or tantalum nitride), and metal silicide (e.g., tungsten silicide, titanium silicide, nickel silicide, or cobalt silicide). In addition, the contact plugs 118a and 118b may contain, for example, polysilicon doped with impurities of the second conductivity as same as the conductivity of the doped lines 106.

The conductive film 120 is preferred to be formed of a conductive material lower than the doped silicon in resistivity. For example, the conductive film 120 may contain a material selected from at least the following of a metal (e.g., tungsten, or molybdenum), conductive metal nitride (e.g., titanium nitride, or tantalum nitride), and metal silicide (e.g., tungsten silicide, titanium silicide, nickel silicide, or cobalt silicide). In addition, the conductive film 120 may contain, for example, polysilicon doped with impurities of the second conductivity.

After that, the conductive film 120 is patterned to form the interconnections 120a shown in FIGS. 2, 3A, and 3B. As aforementioned, the interconnections 120a cross over the doped lines 106 in parallel. One of the interconnections 120a is conductively connected to pluralities of the contact plugs 110a or/and 110b arranged along a column. The interconnections 120a are the bit lines through which data are output.

According to the method for fabricating the mask ROM of the present exemplary embodiment, the coding process is carried out after forming the contact holes 110, and after completing the coding procedure, the contact plugs 118a and 118b and the interconnections 120a are formed. In other words, the processing steps after the coding process are significantly reduced in number in comparison to the conventional fabrication processes. As a result, the time after the coding process until the completion of the mask is ROM can be significantly shortened.

Further, the cell regions of the mask ROM are confined on a plane at the intersecting places of the interconnections 120a and the doped lines 106, thereby providing a highly integrated mask ROM.

Additionally, as the interconnections 120a are correspondent with the bit lines, the data sensing margin with low bit-line resistance may be improved as well.

As described above, the mask ROM of the exemplary embodiments of the invention is comprised of the first and second cell regions. The contact plugs of the first cell regions contact with the isolative doped regions formed in the doped lines, while the contact plugs of the second cell regions contact directly with the doped lines. In a read operation, the first cell region is operating in a conductive state, but the second cell region in a non-conductive state. Thus, the cell regions within the intersecting places between the interconnections and the doped lines may be confined, thereby providing a highly integrated mask ROM.

From using the interconnections with low resistivity as the bit lines, a data sensing margin can be enhanced.

In addition thereto, as the fabrication process for the mask ROM of the exemplary embodiments of the invention includes a step of selectively implanting ionic impurities into the doped lines through the contact holes in coding customers' data information, it is able to distribute the ionic impurities in a uniform depth and to offer a reliable coding operation.

Moreover, the fabrication methods of the exemplary embodiments of the present invention significantly reduces the number of the subsequent processing steps after completing the coding step, which enables a mask ROM to be fabricated in a shorter is TAT from acquisition of data information required by customers.

Having described the exemplary embodiments of the present invention, it is further noted that it is readily apparent to those of reasonable skill in the art that various modifications may be made without departing from the spirit and scope of the invention which is defined by the metes and bounds of the appended claims.

What is claimed is:

1. A mask Read Only Memory (ROM) comprising:
a plurality of doped lines arranged on a substrate of a first conductivity, the doped lines having a second conductivity;
an insulation film covering the substrate;
a plurality of interconnections intersecting the doped lines in parallel and arranged on the insulation film;
an isolative doped region of the first conductivity arranged at the doped line of at least one intersecting place selected from intersecting places between the interconnections and the doped lines;
a first contact plug penetrating the insulation film at the selected intersecting place and connecting the isolative doped region to the interconnection; and
a second contact plug penetrating the insulation film at a deselected intersecting place and connecting the doped line to the interconnection.

2. The mask ROM as set forth in claim 1, wherein the first conductivity is N-type and the second conductivity is P-type,
wherein during a read operation, the mask ROM being adapted to receive a first voltage applied to a selected one of the interconnections which is higher than a second voltage applied to a selected one of the doped lines.

3. The mask ROM as set forth in claim 2, wherein the first voltage is a precharging voltage and the second voltage is a ground voltage.

4. The mask ROM as set forth in claim 1, wherein the first conductivity is P-type and the second conductivity is N-type.
wherein during a read operation, the mask ROM being adapted to receive a first voltage applied to a selected one of the interconnections which is lower than a second voltage applied to a selected one of the doped lines.

5. The mask ROM as set forth in claim 4, wherein the first voltage is a ground voltage and the second voltage is a precharging voltage.

6. The mask ROM as set forth in claim 1, wherein the doped lines are word lines and the interconnections are bit lines.

7. The mask ROM as set forth in claim 1, which further comprises:
a plurality of field isolation films defining linear active regions arranged in parallel With each other in the substrate,
wherein the active regions are isolated from each other and the doped line is disposed in the active region.

8. The mask ROM as set forth in claim 1, wherein the doped line is lower than the isolative doped region in impurity concentration.

9. The mask ROM as set forth in claim 1, wherein the interconnections include a conductive material lower than doped silicon in resistivity.

10. A method of fabricating a mask Read Only Memory (ROM), comprising:
forming a plurality of doped lines in parallel on a substrate of a first conductivity, the doped lines being set in a second conductivity;
forming an insulation film to cover the substrate;
patterning the insulation film to form a plurality of contact holes exposing the doped lines;
implanting ionic impurities into the doped line through a selected contact hole to form an isolative doped region;
forming contact plugs to fill the contact holes; and
forming a plurality of interconnections that intersect the doped lines in parallel on the insulation film and link with the contact plugs.

11. The method as set forth in claim 10, wherein the first conductivity is N-type and the second conductivity is P-type,
wherein during a read operation, the mask ROM formed is adapted to receive a first voltage applied to a selected one of the interconnections which is higher than a second voltage applied to a selected one of the doped lines.

12. The method as set forth in claim 10, wherein the first conductivity is P-type and the second conductivity is N-type,
wherein during a read operation, the mask ROM formed is adapted to receive a first voltage applied to a selected one of the interconnections which is lower than a second voltage applied to a selected one of the doped lines.

13. The method as set forth in claim 10, wherein the doped line is a word line and the interconnection is a bit line.

14. The method as set forth in claim 10, which further comprises:
forming a plurality of field isolation films to define linear active regions arranged in parallel with each other in the substrate,
wherein the doped lines are disposed in the active regions.

15. The method as set forth in claim 10, wherein the forming of the isolative doped regions comprises:
forming a mask pattern to selectively expose and cover the contact holes on the substrate;
implanting ionic impurities of the first conductivity into the substrate through the exposed contact hole under the mask pattern;
removing the mask pattern; and
activating the ionic impurities implanted into the substrate.

16. The method as set forth in claim 10, wherein the doped line is lower than the isolative doped region in impurity concentration.

17. The method as set forth in claim 10, wherein the interconnection includes a conductive material lower than doped silicon in resistivity.
